(19) United States
(12) Patent Application Publication
(10) Pub. No.: US 2024/0334790 A1
(43) Pub. Date: Oct. 3, 2024

(54) DISPLAY PANEL AND MANUFACTURING METHOD THEREOF, AND DISPLAY DEVICE

(71) Applicant: BOE Technology Group Co., Ltd., Beijing (CN)

(72) Inventor: Dejiang ZHAO, Beijing (CN)

(21) Appl. No.: 18/250,792

(22) PCT Filed: Feb. 24, 2022
(86) PCT No.: PCT/CN2022/077756

§ 371 Date: Apr. 27, 2023

(51) Int. Cl. H10K 59/80; H10K 59/12; H10K 59/122

(52) U.S. Cl. CPC H10K 59/878; H10K 59/1201; H10K 59/122

(57) ABSTRACT

The present disclosure provides a display panel and a method for manufacturing the display panel, and a display device, which relates to the field of display technologies. The display panel includes a substrate and a light-emitting structure. The light-emitting structure includes a pixel defining structure, a reflective layer, and a first conductive layer. The reflective layer includes a plurality of reflective parts spaced apart; and the first conductive layer includes a plurality of first conductive parts spaced apart. In a direction parallel to the substrate, a spacing is provided between a side of the reflective part or the first conductive part close to the pixel defining structure and a corresponding side of the pixel defining structure close to the reflective part or the first conductive part.

### CROSS-REFERENCE TO RELATED APPLICATIONS

The present application is the U.S. National phase application of International Application No. PCT/CN2022/077756, filed on Feb. 24, 2022, the entire contents of which are hereby incorporated by reference in its entirety.

### TECHNICAL FIELD

The present disclosure relates to the field of display technologies, and in particular, to a display panel, a method for manufacturing the display panel, and a display device.

### BACKGROUND

The methods of manufacturing organic functional thin film layers for organic light-emitting diode (OLED) include vacuum thermal deposition and a solution-casting method. The solution-casting method is subdivided into methods such as spin coating, ink-jet printing, and screen printing.

In the inkjet printing method, a solvent is used to melt the OLED organic material, and then the material is directly printed on a surface of a substrate to form a light-emitting functional layer. However, due to the constraints of the printing technology itself, the film quality of the formed light-emitting functional layer will be affected due to the coffee-ring effect, etc., which will lead to uneven luminescence.

The above information disclosed in the “BACKGROUND” section is intended only to enhance the understanding of the background of this disclosure, and therefore it may include information that does not constitute prior art known to those of ordinary skill in the art.

### SUMMARY

The purpose of the present disclosure is to provide a display panel that enhances the luminous intensity corresponding to the middle area of the light-emitting device, thereby relatively reducing the influence of the edge area on the display quality.

In order to achieve the above-mentioned purpose, the present disclosure adopts the following technical solutions.

According to a first aspect of the present disclosure, there is provided a display panel, including a substrate and a light-emitting structure on one side of the substrate, where the light-emitting structure includes:
a pixel defining structure on one side of the substrate, configured to define a plurality of pixel regions arranged in an array;
a reflective layer on one side of the substrate, including a plurality of reflective parts spaced apart, a reflective part being within a pixel region;
a first conductive layer on one side, away from the substrate, of the reflective layer, the first conductive layer including a plurality of first conductive parts spaced apart; and
a hole injection layer on one side, away from the substrate, of the first conductive layer, the hole injection layer including a first subpart and a second subpart, where the first subpart is disposed in a middle portion of the pixel region, and the second subpart is disposed in an edge portion of the pixel region; a distance between the middle portion of the pixel region and the pixel defining structure, is equal to or greater than a distance between the edge portion of the pixel region and the pixel defining structure; and in a direction perpendicular to the substrate, at least a portion of the second subpart has a size greater than a size of the first subpart;
where one reflective part corresponds to one first conductive part, and an orthographic projection of the first conductive part on the substrate at least partially overlaps with an orthographic projection of the reflective part on the substrate; and
in a direction parallel to the substrate, a spacing is provided between a side of the reflective part close to the pixel defining structure and a corresponding side of the pixel defining structure close to the reflective part, and/or a spacing is provided between a side of the first conductive part close to the pixel defining structure and a corresponding side of the pixel defining structure close to the first conductive part.

In an exemplary embodiment of the present disclosure, an orthographic projection of the first subpart on the substrate overlaps with the orthographic projection of the reflective part on the substrate, and an overlapping area, between an orthographic projection of the second subpart on the substrate and the orthographic projection of the reflective part on the substrate, is zero; and/or an orthographic projection of the first subpart on the substrate overlaps with the orthographic projection of the first conductive part on the substrate, and an overlapping area, between an orthographic projection of the second subpart on the substrate and the orthographic projection of the first conductive part on the substrate, is zero.

In an exemplary embodiment of the present disclosure, in the direction parallel to the substrate, a first spacing is provided between the side of the reflective part close to the pixel defining structure and the corresponding side of the pixel defining structure close to the reflective part; and
a second spacing is provided between the side of the first conductive part close to the pixel defining structure and the corresponding side of the pixel defining structure close to the first conductive part;
where the first spacing ranges from 1 μm to 3 μm, and the second spacing ranges from 1 μm to 3 μm.

In an exemplary embodiment of the present disclosure, the light-emitting structure further includes:
a second conductive layer between the substrate and the reflective layer, including a plurality of second conductive parts spaced apart, where
an orthographic projection of the pixel region on the substrate is within an orthographic projection of a second conductive part on the substrate; and
in the direction perpendicular to the substrate, one reflective part corresponds to one second conductive part, and an orthographic projection of the second conductive part on the substrate at least partially overlaps with the orthographic projection of the reflective part on the substrate.

In an exemplary embodiment of the present disclosure, the pixel defining structure has, in the direction perpendicular to the substrate, a bottom end close to the substrate, a top end away from the substrate, and a middle part between the bottom end and the top end, the bottom end of the pixel defining structure is configured to define a plurality of openings, the middle part or the top end of the pixel defining structure is configured to define a plurality of light outlets, and one opening corresponds to one second conductive part to expose the second conductive part;
an orthographic projection of a light outlet on the substrate is within an orthographic projection of the opening on the substrate; and
the orthographic projection of the light outlet on the substrate, the orthographic projection of the reflective part on the substrate, and the orthographic projection of the first conductive part on the substrate are at least partially overlapped.

In an exemplary embodiment of the present disclosure, along a direction away from the substrate, the pixel defining structure includes a first part and a second part connected in sequence; and an orthographic projection of the first part on the substrate is within an orthographic projection of the second part on the substrate, and an area of the orthographic projection of the first part on the substrate is smaller than an area of the orthographic projection of the second part on the substrate.

In an exemplary embodiment of the present disclosure, an overlapping area between the orthographic projection of the first conductive part on the substrate and the orthographic projection of the reflective part on the substrate, do not overlap with the orthographic projection of the second part on the substrate; and
at least a portion of an orthographic projection of the first spacing or the second spacing on the substrate is within the orthographic projection of the second part on the substrate.

In an exemplary embodiment of the present disclosure, in the direction perpendicular to the substrate, a height of the first part is greater than or equal to a sum of a thickness of the reflective part and a thickness of the first conductive part.

In an exemplary embodiment of the present disclosure, in the direction perpendicular to the substrate, a side, away from the substrate, of a cross section of the second part is an arc protruding in a direction away from the substrate.

In an exemplary embodiment of the present disclosure, in the direction perpendicular to the substrate, a cross section of the pixel defining structure is in a mushroom shape.

In an exemplary embodiment of the present disclosure, the reflective part has a first surface close to the substrate, a second surface away from the substrate, and a sidewall between the first surface and the second surface, the first conductive part contacting the sidewall and the second surface of the reflective part.

In an exemplary embodiment of the present disclosure, the light-emitting structure further includes:
a first insulating layer between the reflective layer and the first conductive layer, the first insulating layer including a plurality of first insulating parts spaced apart, where a first insulating part is within the pixel region, and the orthographic projection of the reflective part on the substrate is within an orthographic projection of the first insulating part on the substrate.

In an exemplary embodiment of the present disclosure, the first insulating part contacts a sidewall of the reflective part and a surface of the reflective part on a side away from the substrate, and the first insulating part contacts an area of the second conductive part exposed by the reflective part.

In an exemplary embodiment of the present disclosure, the light-emitting structure further includes:
a second insulating layer on a side of the second conductive layer away from the substrate, the second insulating layer including a plurality of second insulating parts spaced apart, where a second insulating part is within the pixel region, and the second insulating part contacts an area of the second conductive part exposed by the reflective part, a sidewall of the first conductive part, a sidewall of the reflective part, and at least a portion of a surface of the first conductive part away from the substrate.

In an exemplary embodiment of the present disclosure, a thickness of the second conductive layer ranges from 8 nm to 18 nm, a thickness of the reflective layer ranges from 60 nm to 150 nm, and a thickness of the first conductive layer ranges from 8 nm to 18 nm; and
in the direction perpendicular to the substrate, a height of the pixel defining structure ranges from 1.2 μm to 2 μm.

In an exemplary embodiment of the present disclosure, the display panel further includes:
a planarization layer on a side of the light-emitting structure close to the substrate, where
the first conductive part is connected to a pixel circuit through a via hole in the planarization layer, and an orthographic projection of the via hole on the substrate and an orthographic projection of the pixel defining structure on the substrate are at least partially overlapped.

In an exemplary embodiment of the present disclosure, the first insulating part includes:
a third subpart on a side of the reflective part away from the substrate;
a fourth subpart in contact with the second conductive part; and
a fifth subpart connected between the third subpart and the fourth subpart, where an angle is between an extension direction of the fifth subpart and the substrate, the angle being acute.

In an exemplary embodiment of the present disclosure, the display panel further includes:
a planarization layer on a side of the light-emitting structure close to the substrate, where
the orthographic projection of the first conductive part on the substrate and an orthographic projection of the pixel defining structure on the substrate are at least partially overlapped; and the first conductive part is in contact, at least in part, with the planarization layer.

In an exemplary embodiment of the present disclosure, the display panel further includes:
a first insulating layer between the reflective layer and the first conductive layer, the first insulating layer including a plurality of first insulating parts spaced apart, where a first insulating part at least partially covers a portion of the second conductive part exposed by the reflective part.

According to a second aspect of the present disclosure, there is provided a method for manufacturing a display panel, including:
providing a substrate; and
forming a light-emitting structure on one side of the substrate;
where forming the light-emitting structure on the side of the substrate comprises:
forming a reflective layer on one side of the substrate, where the reflective layer includes a plurality of reflective parts spaced apart;
forming a first conductive layer on one side of the reflective layer away from the substrate, where the first conductive layer includes a plurality of first conductive parts spaced apart;
forming a pixel defining structure on one side of the substrate, where the pixel defining structure configured to define a plurality of pixel regions arranged in an array, one reflective part being within a pixel region; and
forming a hole injection layer on one side of the first conductive layer away from the substrate, where the hole injection layer includes a first subpart and a second subpart, the first subpart is disposed in a middle portion of the pixel region, and the second subpart is disposed in an edge portion of the pixel region; a distance between the middle portion of the pixel region and the pixel defining structure, is equal to or greater than a distance between the edge portion of the pixel region and the pixel defining structure; and in a direction perpendicular to the substrate, at least a portion of the second subpart has a size greater than a size of the first subpart;
where one reflective part corresponds to one first conductive part, and an orthographic projection of the first conductive part on the substrate at least partially overlaps with an orthographic projection of the reflective part on the substrate; and
in a direction parallel to the substrate, a first spacing is provided between a side of the reflective part close to the pixel defining structure and a corresponding side of the pixel defining structure close to the reflective part, and/or a first spacing is provided between a side of the first conductive part close to the pixel defining structure and a corresponding side of the pixel defining structure close to the first conductive part.

In an exemplary embodiment of the present disclosure, forming the pixel defining structure on one side of the substrate includes:
forming a pre-embedded layer on one side of the first conductive layer away from the substrate, the pre-embedded layer including a plurality of pre-embedded parts spaced apart, where a pre-embedded part covers a surface of the first conductive part away from the substrate, and the pre-embedded part covers at least a sidewall of the first conductive part and a sidewall of the reflective part;
forming the pixel defining structure, where the pixel defining structure covers at least a portion of a top surface of the pre-embedded part and a sidewall of the pre-embedded part; and
removing the pre-embedded layer.

In an exemplary embodiment of the present disclosure, in the direction parallel to the substrate, a distance, between a side of the pre-embedded part away from the reflective part and a side of the reflective part close to the pre-embedded part, is equal to the first spacing.

According to a third aspect of the present disclosure, there is provided a display device including the display panel as described in the first aspect.

In the display panel provided by the present disclosure, the pixel defining structure defines a plurality of pixel regions, the reflective part is located in the pixel region defined by the pixel defining structure, and the reflective part and/or the first conductive part has a spacing between it and the pixel defining structure in the direction parallel to the substrate. That is, the overlapping area between the reflective part and the first conductive part is located in the middle area of the corresponding second conductive part. This structure facilitates the enhancement of the luminous intensity corresponding to the middle area, thereby relatively reducing the influence of the edge area on the display quality.

### BRIEF DESCRIPTION OF THE DRAWINGS

The above and other features and advantages of the present disclosure will become more apparent by a detailed description of exemplary embodiments of the present disclosure with reference to the accompanying drawings.

FIG. 1 is a schematic structural diagram of a display panel in an exemplary embodiment of the present disclosure.

FIG. 2 is a schematic structural diagram of a display panel in another exemplary embodiment of the present disclosure.

FIG. 3 is a schematic structural diagram of a display panel in yet another exemplary embodiment of the present disclosure.

FIG. 4 is a schematic structural diagram of a display panel in yet another exemplary embodiment of the present disclosure.

FIG. 5 is a schematic structural diagram of a display panel in yet another exemplary embodiment of the present disclosure.

FIG. 6 is a schematic structural diagram of a display panel in yet another exemplary embodiment of the present disclosure.

FIG. 7 is a schematic structural diagram of a display panel in yet another exemplary embodiment of the present disclosure.

FIG. 8 is a schematic structural diagram of a display panel in yet another exemplary embodiment of the present disclosure.

FIG. 9 is a schematic structural diagram of a display panel in yet another exemplary embodiment of the present disclosure.

FIG. 10 is a schematic structural diagram of a driver circuit layer of a display panel in an exemplary embodiment of the present disclosure.

FIG. 11 is a schematic diagram of a structure formed by step S241 in an exemplary embodiment of the present disclosure.

FIG. 12 is a schematic diagram of a structure formed by step S242 in an exemplary embodiment of the present disclosure.

FIG. 13 is a schematic diagram of a structure formed by step S243 in an exemplary embodiment of the present disclosure.

FIG. 14 is a SEM image of a middle part of a pixel region of the display panel in FIG. 3.

FIG. 15 is a SEM image of a pixel defining structure in an exemplary embodiment of the present disclosure.

FIG. 16 is a SEM image of the display panel in FIG. 2.

FIG. 17 is a SEM image of a part of the display panel in FIG. 3 close to a pixel defining structure.

FIG. 18 is a SEM image of a cross-section of a light-emitting device connected to a pixel circuit in an exemplary embodiment of the present disclosure.

FIG. 19 is a SEM image of a top view of a connection between an anode of a light-emitting device and a via hole in an exemplary embodiment of the present disclosure.

The reference numerals of main components in the drawings are illustrated as follows.
1—substrate; 2—driver circuit layer; 21—active layer; 22—first gate insulating layer; 23—first gate metal layer; 24—second gate insulating layer; 25—second gate metal layer; 26—interlayer dielectric layer; 27—source and drain layer; PLN—planarizing layer; BFL—buffer layer; 3—light-emitting structure; 31—second conductive layer; 311—second conductive part; 32—reflective layer; 321—reflective part; 33—first conductive layer; 331—first conductive part; 34—first insulating layer; 341—first insulating part; 3411—third subpart; 3412—fourth subpart; 3413—fifth subpart; 35—second insulating layer; 351—second insulating part; 36—light-emitting functional layer; 361—hole injection layer; 3611—first subpart; 3612—second subpart; 362—hole transport layer; 363—light-emitting material layer; 364—electron transport layer; 37—third conductive layer; 38—pixel defining structure; 381—first part; 382—second part; 01—opening; 02—light outlet; 30—light-emitting device; 301—anode; 4—pre-embedded layer; 41—pre-embedded part; 5—via hole.

### DETAILED DESCRIPTION

Exemplary embodiments will now be described more fully with reference to the accompanying drawings. However, the exemplary embodiments can be implemented in various forms and should not be construed as being limited to the examples set forth here; rather, these embodiments are provided so that the present disclosure will be comprehensive and complete, and the concept of the exemplary embodiments will be fully conveyed to those skilled in the art. The described features, structures, or characteristics may be combined in any suitable manner in one or more embodiments. In the following description, many specific details are provided in order to fully understand the embodiments of the present disclosure.

In the figures, the thickness of the areas and layers may be exaggerated for clarity. The same reference numerals in the figures represent the same or similar structures, and thus their detailed descriptions will be omitted.

The features, structures, or characteristics described may be combined in any suitable manner in one or more embodiments. In the following description, many specific details are provided in order to fully understand the embodiments of the present disclosure. However, those of skill in the art will realize that the technical solutions of the present disclosure may be practiced without one or more of the particular details described, or the technical solutions of the present disclosure may be practiced using other methods, components, materials, etc. In other instances, well-known structures, materials, or operations are not shown or described in detail to avoid obscuring the main technical ideas of the present disclosure.

When a structure is “on” other structures, it may mean that the structure is integrally formed on other structures, or that the structure is “directly” arranged on other structures, or that the structure is “indirectly” arranged on other structures through another structure.

The terms “a/an”, “one”, “the/said” are used to indicate the existence of one or more elements/components/etc. The terms “comprising/including” and “having” are used to indicate an open-ended inclusion and mean that additional elements/components/etc. may exist in addition to the listed elements/components/etc. The terms “first” and “second” are used as markers only and are not as restrictions on the number of the objects.

In the related art, ink-jet printing technology is used in the production and preparation of OLED display panels due to its high production efficiency and low material cost. The ink-jet printing technology involves dropping ink-jet droplets into the pixel region and then drying the droplets so that the ink-jet droplets can be cured to form a light-emitting functional layer. However, although this method can be made easily, the evaporation rate at the edge position is greater than that at the middle position during the drying process of ink-jet droplets, leading to an outward capillary flow inside the ink-jet droplets, carrying the suspended particles to the edge position and depositing them into rings at the edge position, resulting in the thickness at the edge position being greater than that at the middle position and the coffee ring effect, which interferes with the microcavity effect, causes the chromaticity to shift, and affects the display quality of the OLED display panel.

As shown in FIGS. 1 to 9, the present disclosure provides a display panel including a substrate 1 and a light-emitting structure 3 disposed on one side of the substrate 1. The light-emitting structure 3 includes a pixel defining structure 38, a reflective layer 32, a first conductive layer 33, and a hole injection layer 361. The pixel defining structure 38 is disposed on one side of the substrate 1 and the plurality of pixel defining structures 38 define a plurality of pixel regions arranged in an array. The reflective layer 32 is disposed on one side of the substrate 1 and includes a plurality of reflective parts 321 spaced apart. The reflective part 321 is disposed within the pixel region. The first conductive layer 33 is disposed on the side of the reflective layer 32 away from the substrate 1 and includes a plurality of first conductive parts 331 spaced apart. The hole injection layer 361 is disposed on one side of the first conductive layer 33 away from the substrate 1 and includes a first subpart 3611 and a second subpart 3612. The first subpart 3611 is disposed in a middle portion of the pixel region, and the second subpart 3612 is disposed in an edge portion of the pixel region. The distance between the middle portion of the pixel region and the pixel defining structure 38 is greater than or equal to the distance between the edge portion of the pixel region and the pixel defining structure 38. In a direction perpendicular to the substrate substrate 1, at least a portion of the second subpart 3612 has a size greater than a size of the first subpart 3611. The plurality of reflective parts 321 are in one-to-one correspondence with the plurality of first conductive parts 331, and an orthographic projection of the first conductive portion 331 on the substrate 1 at least partially overlaps with an orthographic projection of the reflective part 321 on the substrate 1. In a direction parallel to the substrate 1, a first spacing L1 is provided between a side of the reflective part 321 close to the pixel defining structure 38 and a corresponding side of the pixel defining structure 38 close to the reflective part 321.

In the display panel provided in the present disclosure, the pixel defining structures 38 define a plurality of pixel regions, and the reflective part 321 is disposed within a pixel region defined by the pixel defining structures 38, and the reflective part 321 and/or the first conductive part 331 has a spacing between the pixel defining structure 38 in the direction parallel to the substrate substrate 1. That is, an overlapping area of the reflective part 321 and the first conductive part 331 corresponds to the middle area of the light-emitting structure, which facilitates the enhancement of the luminous intensity corresponding to this middle area, thereby relatively reducing the influence of the edge area on the display quality.

In addition, since there is spacing provided between the reflective part 321 and the pixel defining structure 38 or between the first conductive part 331 and the pixel defining structure 38 in the present disclosure, the formed reflective part 321 or first conductive part 331 may be step-like at the edge area. This structural design helps to improve the thickness and flatness at the edge position of the film layer when other film layers are subsequently formed by the ink-jet printing method, and thus helps to reduce the impact on the display quality due to the coffee-ring effect in related art.

The components of the display panel provided by the embodiments of the present disclosure are described in detail below in conjunction with the accompanying drawings.

As shown in FIGS. 1 to 9, according to some embodiments of the present disclosure, there is provided a display panel, which may be an Organic Light-Emitting Diode (OLED) display panel or a Quantum Dot Light Emitting Diodes (QLED) display panel. The display panel includes a substrate 1 and a light-emitting structure 3 disposed on one side of the substrate 1. The light-emitting structure 3 includes a pixel defining structure 38, a reflective layer 32, and a first conductive layer 33.

The substrate 1 may be made of an inorganic material or an organic material. For example, in one embodiment of the present disclosure, the material of the substrate 1 may be a glass material such as soda-lime glass, quartz glass, sapphire glass, or may be a metal material such as stainless steel, aluminum, nickel, etc. In another embodiment of the present disclosure, the material of the substrate 1 may be polymethyl methacrylate (PMMA), polyvinyl alcohol (PVA), polyvinyl phenol (PVP), polyether sulfone (PES), polyimide (PI), polyamide, polyacetal, poly carbonate (PC), polyethylene terephthalate (PET), polyethylene naphthalate (PEN), or a combination thereof. The substrate 1 may also be a flexible substrate 1. For example, in one embodiment of the present disclosure, the material of the substrate 1 may be polyimide (PI). The substrate 1 may also be a composite of multiple layers of material. For example, in one embodiment of the present disclosure, the substrate 1 may include a bottom film layer (Bottom Film), a pressure-sensitive adhesive layer, a first polyimide layer, and a second polyimide layer that are stacked in sequence.

As shown in FIG. 1, the light-emitting structure 3 is disposed on one side of the substrate 1, and the light-emitting structure 3 can be used to form a light-emitting device to complete the screen display. The light-emitting structure 3 includes a pixel defining structure 38, a reflective layer 32, and a first conductive layer 33.

The pixel defining structure 38 is disposed on one side of the substrate 1, and the plurality of pixel defining structures 38 define a plurality of pixel regions arranged in an array. The shape of the orthographic projection of the pixel region on the substrate 1 may be a polygon, a smooth curved closed pattern, or other pattern, which is not specifically limited in the present disclosure.

The reflective layer 32 is disposed on one side of the substrate 1, and the reflective layer 32 includes a plurality of reflective parts 321 spaced apart, with the reflective parts 321 disposed within the pixel regions. The material of the reflective layer 32 may include a conductive material, such as a conductive metal material or an alloy material, etc. In one embodiment, the material of the reflective layer 32 may include a metallic material such as silver, aluminum, etc.

The first conductive layer 33 is disposed on the side of the reflective layer 32 away from the substrate 1, and the first conductive layer 33 includes a plurality of first conductive parts 331 spaced apart. The first conductive parts 331 are in one-to-one correspandance with the reflective parts 321 in the direction perpendicular to the substrate 1, i.e., in the Y direction. The orthographic projection of the first conductive part 331 on the substrate 1 and the orthographic projection of the reflective part 321 on the substrate are at least partially overlapped. Specifically, the orthographic projection of the reflective part 321 on the substrate 1 may be located within the orthographic projection of the first conductive part 331 on the substrate 1, or the orthographic projection of the reflective part 321 on the substrate 1 may be completely overlapped with the orthographic projection of the first conductive part 331 on the substrate 1. In the present disclosure, completely overlapping means that the shape, size and position are substantially the same. For example, as shown in FIG. 1, in some embodiments, the reflective part 321 has a first surface close to the substrate 1 and a second surface away from the substrate 1, and a sidewall between the first surface and the second surface; and the first conductive part 331 contacts the second surface and the sidewall of the reflective part 321, and the first conductive part 331 extends to the bottom end of the pixel defining structure 38, i.e., the end of the pixel defining structure 38 close to the substrate 1. In these embodiments, the orthographic projection of the reflective part 321 on the substrate 1 may be located within the orthographic projection of the first conductive part 331 on the substrate 1.

The first conductive layer 33 may be made transparent conductive material, such as Indium Tin Oxide (ITO), Indium Zinc Oxide (IZO), etc. The first conductive layer 33 may be a single-layer or multi-layer structure. In one embodiment, the first conductive layer 33 is a single-layer structure, made of ITO material.

In the present disclosure, the reflective part 321 is located within the pixel region, and the reflective part 321 and the first conductive part 331 are at least partially overlapped, which helps to improve the reflectivity of the light emitted by the light-emitting device through the reflective part 321 and enhance the luminous intensity of the light-emitting device.

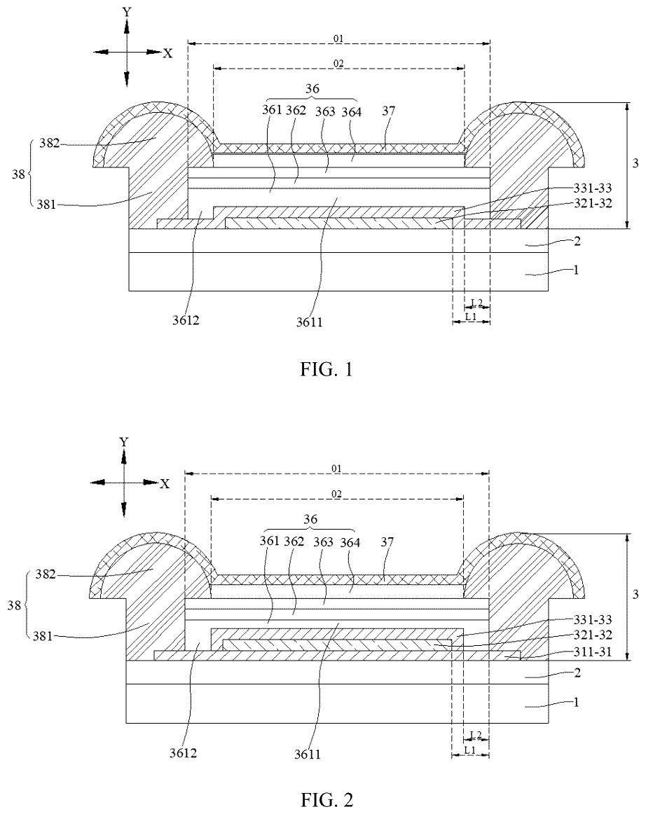

As shown in FIG. 2, in some other embodiments of the present disclosure, the light-emitting structure 3 further includes a second conductive layer 31. The second conductive layer 31 is disposed between the substrate 1 and the reflective layer 32, and includes a plurality of second conductive parts 311 spaced apart. The plurality of second conductive parts 311 are arranged in an array. The second conductive layer 31 may be made of transparent conductive material, such as Indium Tin Oxide (ITO), Indium Zinc Oxide (IZO), etc. The orthographic projection of the second conductive part 311 on the substrate 1 may be a circle, an ellipse, a regular polygon or may be a curved-edge graphic or an irregular polygon, etc., which is not specifically limited by the present disclosure. The second conductive layer 31 may be a single-layer or multi-layer structure. In one embodiment, the second conductive layer 31 is a single-layer structure, made of ITO material.

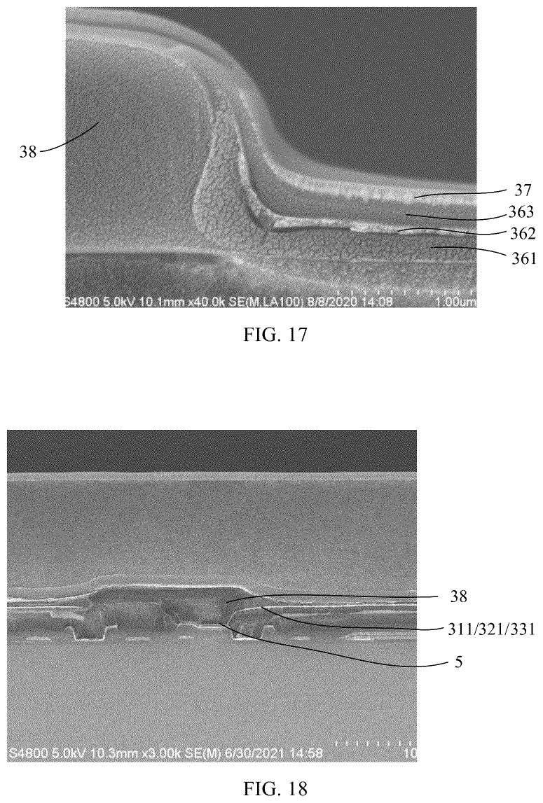

It should be noted here that when the light-emitting structure also includes the second conductive layer 31, the first conductive part 331 may not extend to the bottom end of the pixel defining structure 38, and it may contact the second surface of the reflective part 321 on the side away from the substrate 1, and the corner of the second surface and the side wall of the reflective part 321. As shown in FIG. 16, in the actual process, when the first conductive layer 33 is formed, the first conductive part 331 may include a sub-conductive part 3311 that contacts the second surface of the reflective part 321 and a sub-conductive part 3312 that does not contact the second surface of the reflective part 321, the sub-conductive part 3312 having an angle between the extension direction of the sub-conductive part 3312 and the second conductive part 311, and the angle being an acute angle.

The pixel defining structure 38 is disposed on one side of the substrate 1, and a plurality of pixel defining structures 38 define a plurality of pixel regions arranged in an array. The second conductive parts 311 are exposed in the pixel regions, respectively, and the orthographic projection of the pixel region on the substrate 1 is located within the orthographic projection of the second conductive part 311 on the substrate 1. That is, the extent of the pixel region is located within the boundary of its corresponding second conductive part 311.

The reflective parts 321 are in one-to-one correspondence with the second conductive parts 311 in the direction perpendicular to the substrate 1, i.e., in the Y direction. The orthographic projection of the second conductive part 311 on the substrate 1 and the orthographic projection of the reflective part 321 on the substrate 1 are at least partially overlapped.

In some embodiments, the orthographic projection of the reflective part 321 on the substrate 1 is located within the orthographic projection of the second conductive part 311 on the substrate 1, and the area of the orthographic projection of the reflective part 321 on the substrate 1 is smaller than the area of the second conductive part 311 exposed by the pixel region.

In the present disclosure, as shown in FIGS. 1 and 2, in the direction parallel to the substrate 1, a spacing is provided between the side of the reflective part 321 close to the pixel defining structure 38 and a corresponding side of the pixel defining structure 38 close to the reflective part 321, or a spacing is provided between the side of the first conductive part 331 close to the pixel defining structure 38 and a corresponding side of the pixel defining structure 38 close to the first conductive part 331. Specifically, a spacing is provided between the reflective part 321 and the pixel defining structure 38, or a spacing is provided between the first conductive part 331 and the pixel defining structure 38.

As shown in FIGS. 1 and 2, in some embodiments of the present disclosure, in the direction parallel to the substrate 1, a first spacing L1 is provided between the side of the reflective part 321 close to the pixel defining structure 38 and the corresponding side of the pixel defining structure 38 close to the reflective part 321. As shown in FIG. 2, when the display panel is also provided with the second conductive part 311, the reflective part 321 is not provided above the region of the second conductive part 311 corresponding to the first spacing L1.

Continuing to refer to FIGS. 1 and 2, in the X direction, the size of the first spacing L1 can be set according to the actual situation. For example, in some embodiments, the size of the first spacing L1 may range from 1 μm to 3 μm, and specifically may be 1.1 μm, 1.2 μm, 1.3 μm, 1.4 μm, 1.5 μm, 1.7 μm, 1.9 μm, 2 μm, 2.1 μm, 2.2 μm, 2.3 μm, 2.4 μm, 2.5 μm, 2.7 μm, 2.9 μm, or 3 μm, etc., but not limited thereto.

In some embodiments, the orthographic projection of the first conductive part 331 on the substrate 1 is located within the orthographic projection of the second conductive part 311 on the substrate 1, and the area of the orthographic projection of the first conductive portion 331 is smaller than the area of the second conductive part 311 exposed by the pixel region. In the direction parallel to the substrate 1, a second spacing L2 is provided between the side of the first conductive part 331 close to the pixel defining structure 38 and the corresponding side of the pixel defining structure 38 close to the first conductive part 331. As shown in FIG. 2, when the display panel is also provided with the second conductive part 311, the first conductive part 331 is not provided above the region of the second conductive part 311 corresponding to the second spacing L2.

As shown in FIGS. 1 and 2, in the X direction, the first conductive part 331 is not provided above the region of the second conductive part 311 corresponding to the second spacing L2. The size of the second spacing can be set according to the actual situation. For example, in some embodiments, the size of the second spacing may range from 1 μm to 3 μm, and specifically may be 1.1 μm, 1.2 μm, 1.3 μm, 1.4 μm, 1.5 μm, 1.7 μm, 1.9 μm, 2 μm, 2.1 μm, 2.2 μm, 2.3 μm, 2.4 μm, 2.5 μm, 2.7 μm, 2.9 μm, or 3 μm, etc., but not limited thereto. In some embodiments, the first spacing L1 is equal to the sum of the second spacing L2 and the thickness of the first conductive part 331.

In the present disclosure, the second conductive layer 31, the reflective layer 32 and the first conductive layer 33 are all film layers having a certain thickness. The thickness of the reflective layer 32 is not less than the sum of the thickness of the second conductive layer 31 and the thickness of the first conductive layer 33. In an embodiment, the thickness of the second conductive layer 31 ranges from 8 nm to 18 nm, and specifically may be 8 nm, 10 nm, 12 nm, 13 nm, 15 nm, 16 nm, 17 nm or 18 nm, but not limited thereto. The thickness of the reflective layer 32 ranges from 60 nm to 150 nm, and specifically may be 60 nm, 65 nm, 70 nm, 75 nm, 80 nm, 85 nm, 90 nm, 95 nm, 100 nm, 105 nm, 115 nm, 120 nm, 125 nm, 130 nm, 135 nm, 140 nm, 145 nm, or 150 nm, but not limited thereto. The thickness of the first conductive layer 33 ranges from 8 nm to 18 nm, and specifically may be 8 nm, 10 nm, 12 nm, 13 nm, 15 nm, 16 nm, 17 nm, or 18 nm, but not limited thereto.

In the present disclosure, the light-emitting structure 3 includes a plurality of light-emitting devices, each of which is located within a pixel region. The light-emitting devices may be OLEDs, or QLEDs, etc.

In some embodiments, the first conductive part 331 and the reflective part 321 may serve as the anode of the light-emitting device. In other embodiments, the second conductive part 311, the reflective part 321, and the first conductive part 331 may serve as the anode of the light-emitting device. In yet other embodiments, the first conductive part 331 may serve as the anode of the light-emitting device.

As shown in FIGS. 1 to 9, in some embodiments of the present disclosure, the light-emitting structure 3 also includes a light-emitting functional layer 36 and a third conductive layer 37. The light-emitting functional layer 36 is disposed on the side of the first conductive layer 33 away from the substrate 1. In the present disclosure, the ink-jet printing method can be used to form the light-emitting functional layer 36. The light-emitting functional layer 36 is a multi-layer structure, and along the direction away from the substrate 1, the light-emitting functional layer 36 includes a hole injection layer 361, a hole transport layer 362, light-emitting material layer 363, electron transport layer 364. Visible light can be generated by making holes and electrons in the light-emitting material layer 363 compounded into excitons and radiating photons from the excitons. The specific light-emitting principle is not detailed here. The light-emitting material layer 363 can be organic light-emitting material layer or quantum dot light-emitting material layer. The light-emitting functional layer 36 includes a plurality of light-emitting functional parts which are located one by one in each pixel region. The thickness of the light-emitting functional layer 36 may range from 200 nm to 500 nm, and the specific thickness can be set according to the actual situation. In some embodiments, the light-emitting functional layer 36 can also include an electron injection layer, provided on the side of the electron transport layer 364 away from the substrate 1.

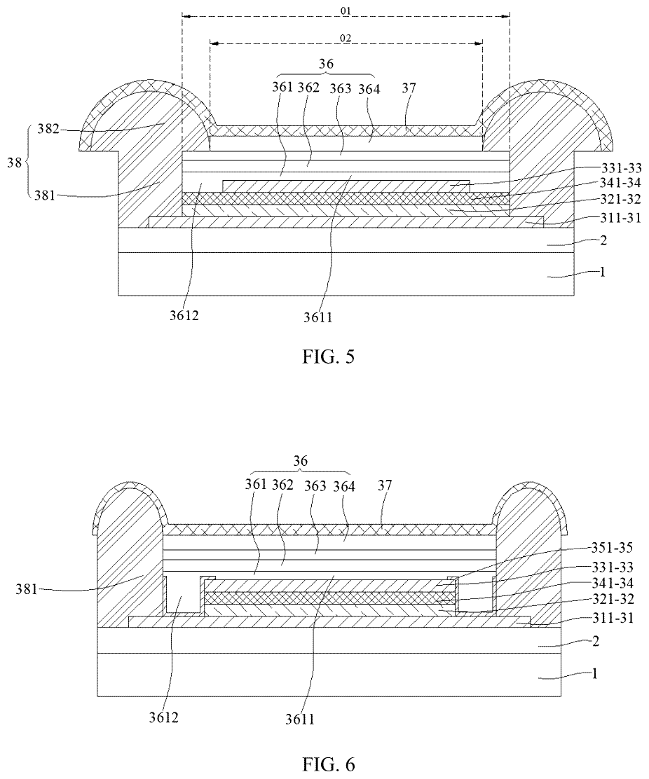

In some embodiments of the present disclosure, the hole injection layer 361 is disposed on the side of the first conductive layer 33 away from the substrate 1, and includes a first subpart 3611 and a second subpart 3612. As shown in FIGS. 1 to 4, FIG. 5, and FIGS. 6 to 9, the first subpart 3611 is located in the middle portion of the pixel region, the second subpart 3612 is located in the edge portion of the pixel region, and the distance between the middle portion of the pixel region and the pixel defining structure 38 is not less than the distance between the edge portion of the pixel region and the pixel defining structure 38. Specifically, as shown in FIGS. 1 to 4, and FIGS. 6 to 9, the orthographic projection of the first subpart 3611 on the substrate 1 overlaps with the orthographic projection of the reflective part 321 on the substrate 1, and the orthographic projection of the second subpart 3612 on the substrate 1 does not overlap with the orthographic projection of the reflective part 321 on the substrate 1. Alternatively, as shown in FIG. 5, the orthographic projection of the first subpart 3611 on the substrate 1 overlaps with the orthographic projection of the first conductive part 331 on the substrate 1, and the orthographic projection of the second subpart 3612 on the substrate 1 does not overlap with the orthographic projection of the first conductive part 331 on the substrate 1. In the direction perpendicular to the substrate 1, the size of at least a portion of the area of the second subpart 3612 is larger than the size of the first subpart 3611.

The third conductive layer 37 is provided on the side of the light-emitting functional layer 36 away from the substrate 1. The third conductive layer 37 may serve as a cathode of the light-emitting device. The third conductive layer 37 can be a single-layer or multi-layer structure, and the material of the third conductive layer 37 can include one or more kinds of conductive metal, metal oxide, and alloy.

All light-emitting devices may share the same cathode. Specifically, the third conductive layer 37 is a continuous conductive layer covering the light-emitting functional layer 36 and the pixel defining structure 38 of each light-emitting device. That is, the orthrographic projection of the third conductive layer 37 on the substrate 1 covers all pixel regions and the orthrographic projection of the pixel defining structures 38 on the substrate 1. In addition, the third conductive layer 37 is recessed into the pixel region at the place it corresponds to the pixel region, i.e., recessed towards the substrate 1 at the place corresponding to the pixel region.

In the present disclosure, in addition to improving the luminous intensity of the middle region by the above embodiments, which reduces the influence of the edge region on the display quality to a relative extent, the display quality of the display panel can be further improved in other ways.

Methods for further improving the display quality of the display panel will be described in detail below in conjunction with different embodiments.

As shown in FIG. 1, in some embodiments of the present disclosure, the reflective part 321 and the first conductive part 331 serve as the anode of the light-emitting device. Alternatively, as shown in FIG. 2, in some embodiments of the present disclosure, the second conductive part 311, the reflective part 321, and the first conductive part 331 serve as the anode of the light-emitting device.

As shown in FIGS. 1 and 2, the first conductive part 331 contacts the sidewall of the reflective part 321 and the surface of the reflective part 321 on the side away from the substrate 1. That is, the first conductive part 331 wraps the reflective part 321. In practical applications, the reflective part 321 is usually a film layer with a certain thickness made of metal material, which has a high edge rigidity and may cause damage, such as scratching and breaking, to the film layer formed subsequently. In this embodiment, the first conductive part 331 wraps the reflective part 321, which helps prevent breakage when forming the subsequent film layer.

In FIG. 1, the first conductive part 331 may further extend to the bottom end of the pixel defining structure 38, and the first conductive part 331 and the reflective part 321 are in contact with each other to form the anode of the light-emitting device. In FIG. 2, the first conductive part 331 may or may not extend to the bottom end of the pixel defining structure 38, without specific limitation by the present disclosure. When the first conductive part 331 does not extend to the bottom end of the pixel defining structure 38, there is a second spacing L2 between the first conductive part 331 and the pixel defining structure 38. In FIG. 2, the first conductive part 331, the reflective part 321, and the second conductive part 311 are in contact with each other to form the anode of the light-emitting device.

In these embodiments, the specific shape of the pixel defining structure 38 may be improved to limit the light emitted from the edge portion of the light-emitting device located within the pixel region. This can be achieved specifically by changing the dimensions of the pixel defining structure 38 in the direction parallel to the substrate 1. For example, in the direction perpendicular to the substrate 1, the pixel defining structure 38 has a bottom end close to the substrate 1, a top end away from the substrate 1, and a middle part between the bottom end and the top end. The bottom ends of the pixel defining structures 38 define a plurality of openings 01. In FIG. 2, when the display panel further includes the second conductive part 311, the opening 01 exposes a portion of the second conductive part 311. The middle parts or top ends of the pixel defining structures 38 define a plurality of light outlets 02. The range of the light outlet 02 is smaller than the range of the opening 01, i.e., the orthographic projection of the light outlet 02 on the substrate 1 is within the orthographic projection of the opening 01 on the substrate 1.

Further, the orthographic projections of the light outlet 02, the reflective part 321, and the first conductive part 331 on the substrate 1 are at least partially overlapped. Preferably, the overlapping area of the orthographic projections of the reflective part 321 and the first conductive part 331 on the substrate 1 overlaps completely with the orthographic projection of the light outlet 02 on the substrate 1. Alternatively, the orthographic projection of the light outlet 02 on the substrate 1 is located within the orthographic projection of the reflective part 321 on the substrate 1 and the orthographic projection of the first conductive portion 331 on the substrate 1. In this way, the pixel defining structure 38 can block the light that may be emitted from the area corresponding to the edge position of the second conductive part 311, thereby avoiding this area from affecting the microcavity effect.

Continuing to refer to FIG. 1 or FIG. 2, the specific shape of the pixel defining structure 38 may be set according to actual requirements. In a specific embodiment, along the direction away from the substrate 1, the pixel defining structure 38 includes a first part 381 and a second part 382 connected in sequence, where the orthographic projection of the first part 381 on the substrate 1 is located within the orthographic projection of the second part 382 on the substrate 1, and the area of the orthographic projection of the first part 381 on the substrate 1 is smaller than the area of the orthographic projection of the second part 382 on the substrate 1. In these embodiments, the second part 382 in the pixel defining structure 38 defines the range of the light outlet 02 and the end of the first part 381 close to the substrate 1 defines the range of the opening 01.

The overlapping area of the orthographic projection of the first conductive part 331 on the substrate 1 and the orthographic projection of the reflective part 321 on the substrate 1, does not overlap with the orthographic projection of the second part 382 on the substrate 1; and at least part of the orthographic projection of the first spacing L1 or the second spacing L2 on the substrate 1 is located within the orthographic projection of the second part 382 on the substrate 1. That is, the light that may be emitted from the area corresponding to the edge position of the second conductive part 311 is blocked by using the second part 382 of the pixel defining structure 38.

In the direction perpendicular to the substrate 1, the height of the first part 381 is not less than the sum of the thicknesses of the reflective part 321 and the first conductive part 331. That is, in the direction perpendicular to the substrate 1, the reflective part 321 and the first conductive part 331 formed are located substantially on the side of the second part 382 close to the substrate 1. Further, the height of the first part 381 is greater than the sum of the thicknesses of the reflective part 321 and the thickness of the first conductive part 331.

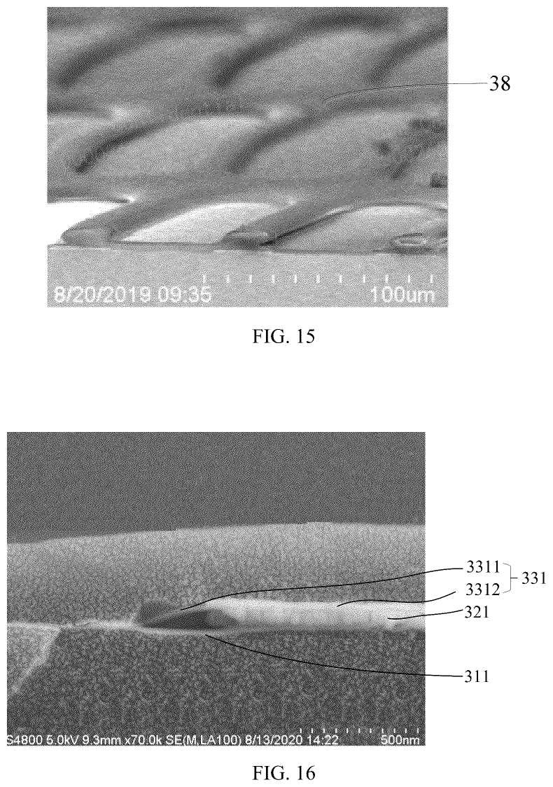

In one embodiment, in the direction perpendicular to the substrate 1, the first part 381 has a cross section that is substantially rectangular in shape, which may be trapezoidal or irregularly polygonal, etc. In the direction perpendicular to the substrate 1, the cross section of the second part 382 is an arc on the side away from the substrate 1 that protrudes in a direction away from the substrate 1. The curved design helps to avoid breakage of the subsequent film layer, such as the cathode layer. Further, in the direction perpendicular to the substrate 1, the pixel defining structure 38 has a cross section in the shape of a mushroom. In the present disclosure, the mushroom shape is substantially an open umbrella-like structure with a substantially columnar bottom and a substantially hemispherical top. In practice, the specific shape of the pixel defining structure 38 may be shown in FIG. 15, which shows a scanning electron microscope (SEM) view of the actual pixel defining structure 38.

In one embodiment, the pixel defining structure 38 has a height ranging from 1.2 μm to 2 μm in the direction perpendicular to the substrate 1. Specifically, it may be 1.2 μm, 1.3 μm, 1.4 μm, 1.5 μm, 1.6 μm, 1.7 μm, 1.8 μm, 1.9 μm, or 2 μm, but is not limited thereto.

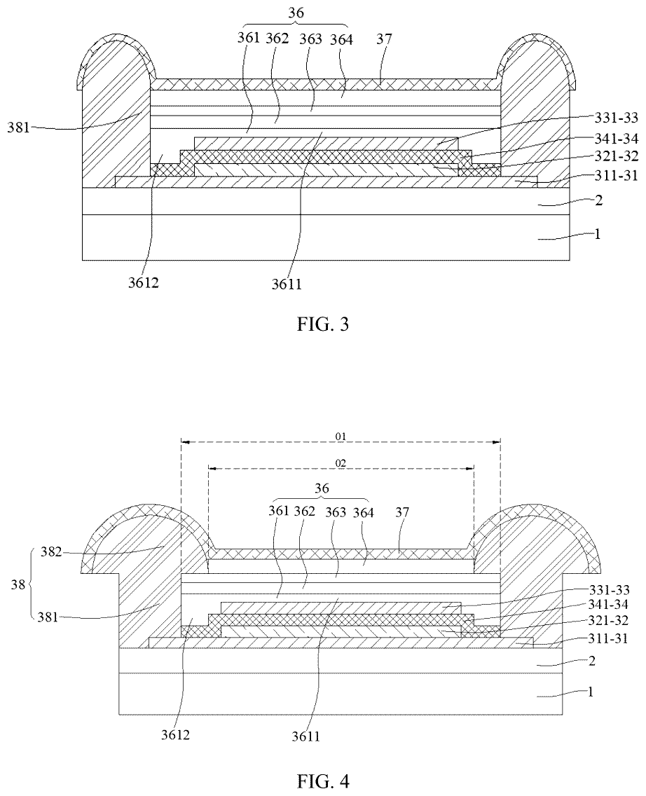

As shown in FIGS. 3 to 7, in some other embodiments of the present disclosure, the first conductive part 331 may serve as the anode of the light-emitting device. In these embodiments, there is a spacing between the first conductive part 331 and the pixel defining structure 38, so that the light can be emitted only from the area corresponding to the first conductive part 331, while no light is emitted from the other edge area, thereby improving the effect of edge areas on the quality of the display screen.

Specifically, in some embodiments, the display panel further includes a first insulating layer 34.

As shown in FIGS. 3 to 7, in one embodiment, the first insulating layer 34 is provided between the reflective layer 32 and the first conductive layer 33, and the first insulating layer 34 includes a plurality of first insulating parts 341 spaced apart. The first conductive part 331, the first insulating part 341, the reflective part 321 and the second conductive part 311 correspond to each other in the direction perpendicular to the substrate 1, and each of the first insulating parts 341 is located within each pixel region correspondingly.

The first insulating part 341 is located within the pixel region, and the orthographic projection of the reflective part 321 on the substrate 1 is located within the orthographic projection of the first insulating part 341 on the substrate 1. The thickness of the first insulating layer 34 ranges from 30 nm to 100 nm, which may be specifically 30 nm, 35 nm, 40 nm, 45 nm, 50 nm, 55 nm, 60 nm, 65 nm, 70 nm, 75 nm, 80 nm, 85 nm, 90 nm, 95 nm, or 100 nm, but is not limited thereto. The material of the first insulating layer 34 includes an inorganic material, such as silicon nitride or silicon dioxide.

As shown in FIGS. 3 and 4, when there is a spacing between the reflective part 321 and the pixel defining structure 38, the first insulating part 341 contacts the sidewall of the reflective part 321 and the surface of the reflective part 321 on the side away from the substrate 1, and the first insulating part 341 contacts the area where the second conductive part 311 is exposed by the reflective part 321. That is, the first insulating part 341 insulates and isolates the second conductive part 311 and the reflective part 321 from the first conductive part 331, so that the first conductive part 331 serves as the anode of the light-emitting device. In this embodiment, the orthrographic projection of the first conductive part 331 on the substrate 1 may be completely overlapped with the orthrographic projection of the reflective part 321 on the substrate 1, i.e., the width of the first conductive part 331 is substantially equal to the width of the reflective part 321 in a direction parallel to the substrate 1. As shown in FIG. 5, when there is no spacing between the reflective part 321 and the pixel defining structure 38, the first insulating part 341 contacts the surface of the reflective part 321 on the side away from the substrate 1.

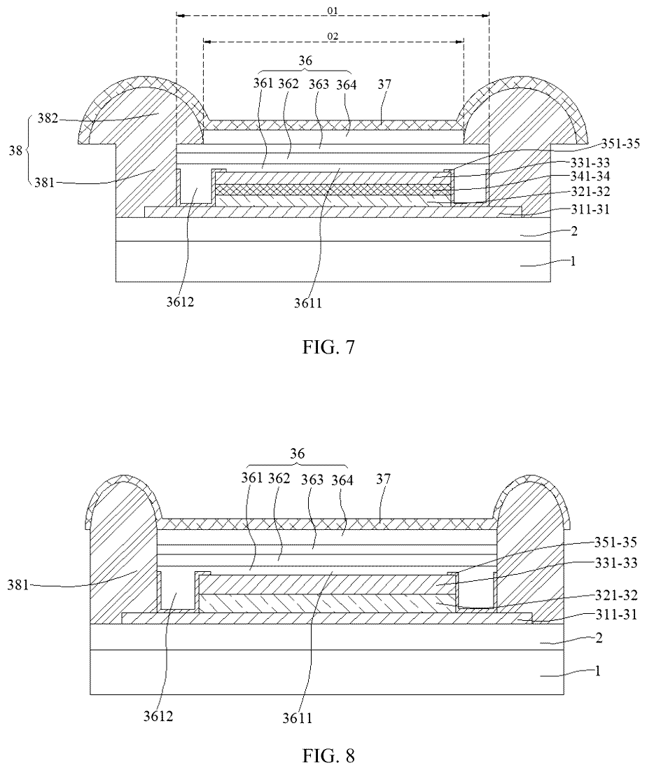

As shown in FIGS. 6 and 7, in another embodiment, the first insulating part 341 does not contact the area of the second conductive part 311 exposed by the reflective part 321 and only contacts the surface of the reflective part 321 on the side away from the substrate 1. In this embodiment, the orthrographic projections of the first conductive part 331, the first insulating part 341, and the reflective part 321 on the substrate 1 completely overlap. That is, the orthographic projections of the first conductive part 331, the first insulating part 341, and the reflective part 321 on the substrate 1 have substantially the same shape, size, and position.

In this embodiment, the display panel further includes a second insulating layer 35 disposed on a side of the second conductive layer 31 away from the substrate 1. The second insulating layer 35 includes a plurality of second insulating parts 351 spaced apart and disposed within the pixel regions. The second insulating part 351 contacts the area of the second conductive part 311 exposed by the reflective part 321, the sidewalls of the first conductive part 331, the first insulating part 341, and the reflective part 321, and at least a portion of the surface of the first conductive part 331 away from the substrate 1, to prevent oxidation of the reflective part 321, etc. In this embodiment, the area of the second conductive part 311 exposed by the reflective part 321 is covered by the second insulating part 351, and the reflective part 321 is covered by the first insulating part 341, so that the first conductive part 331 can be used as the anode of the light-emitting device.

The thickness of the second insulating layer 35 ranges from 10 nm to 20 nm, which may be specifically 10 nm, 11 nm, 12 nm, 13 nm, 14 nm, 15 nm, 16 nm, 17 nm, 18 nm, 19 nm, or 20 nm, but is not limited thereto. The material of the second insulating layer 35 includes an inorganic material, such as silicon nitride or silicon dioxide, etc.

The shape and size of the second insulating part 351 can be set according to the first spacing L1 or the second spacing L2, etc. In an embodiment, in the direction parallel to the substrate 1, the size of the second insulating part 351 is substantially equal to the first spacing L1. That is, in the X direction, the width of the second insulating part 351 is substantially equal to the first spacing L1. In the direction perpendicular to the substrate 1, the height of the second insulating part 351 is substantially the sum of the thicknesses of the first conductive part 331, the thicknesses of the first insulating part 341, and the thicknesses of the reflective part 321. In one embodiment, the second insulating portion 351 may cover a portion of the sidewall of the pixel defining structure 38 close to the reflective part 321 or the first conductive part 331. In the direction perpendicular to the substrate 1, the second insulating part 351 has a cross section in a shape of a groove.

It should be noted that, as shown in FIG. 8, when the display panel further includes the second insulating layer 35, the display panel may not include the first insulating layer 34. In this case, the first conductive part 331, the reflective part 321 and part of the second conductive part 311 may serve as the anode of the light-emitting device.

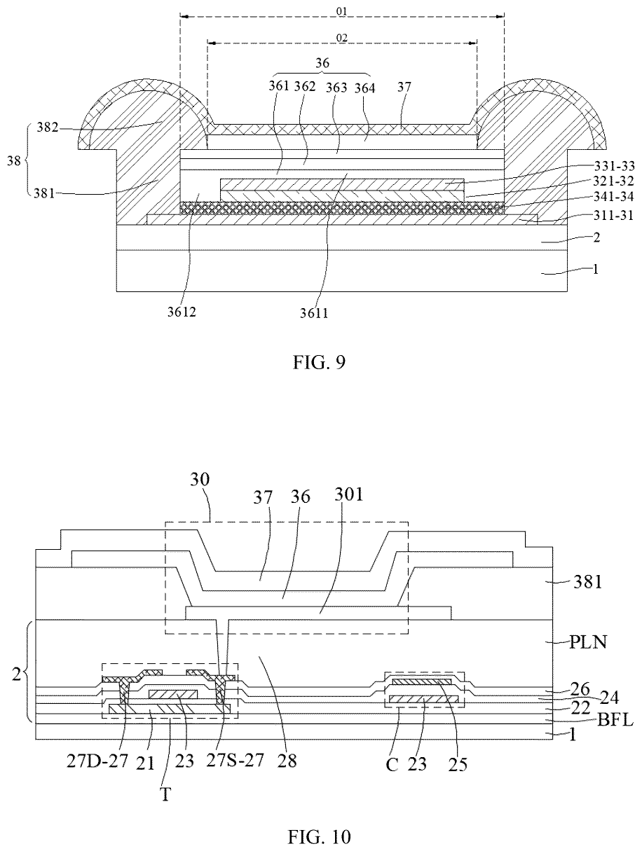

In addition, the luminescence in the edge region of the light-emitting device may be limited by adjusting the position relationship of the individual film layers in the present disclosure, etc. As shown in FIG. 9, in some other embodiments of the present disclosure, the first insulating layer 34 is provided between the reflective layer 32 and the second conductive layer 31, and the first insulating layer 34 includes a plurality of first insulating parts 341 spaced apart. The first insulating part 341 contacts the portion of the second conductive part 311 exposed by the reflective part 321. In this embodiment, the first conductive part 331 and the reflective part 321 may serve as the anode of the light-emitting device.

When the display panel includes an insulating layer, such as the first insulating layer 34 or the second insulating layer 35, the specific shape of the pixel defining structure 38 is not particularly limited, and it may be in the form of a column, an inverted trapezoid, or the like commonly used in the art. As shown in FIGS. 3 and 6, the cross section of the pixel defining structure 38 is a column with an arced top in the direction perpendicular to the plane of the substrate 1. Of course, as shown in FIG. 4 and FIG. 7, etc., the pixel defining structure 38 with a cross section of mushroom shape in the preceding embodiments may also be adopt, without any limitation in the present disclosure.

In the above embodiments of the present disclosure, the reflective part 321 and the first conductive part 331 are provided so that the light-emitting device has a stepped shape at the edge area of the second conductive part 311, the reflective part 321 and the first conductive part 331. This structural design helps to improve the thickness and flatness at the edge of the film layer when the light-emitting functional layer 36 is subsequently formed by ink jet printing method, as shown in FIG. 14. FIG. 14 may correspond to the embodiment shown in FIG. 3 or FIG. 4.

FIG. 14 shows the SEM image of various film layers formed at the edge of the light-emitting device, i.e., the side close to the pixel defining structure. As can be seen from the figure, at the edge position A, the thickness of each film layer formed is normal and flat, such as the hole injection layer 361, the hole transport layer 362, the light-emitting material layer 363, and the electron transport layer 364. Thus, it helps to improve the impact on the display quality due to the coffeering effect in the related art.

Continuing to refer to FIG. 14, in the actual process, the formed first insulating part 341 includes a third subpart 3411, a fourth subpart 3412, and a fifth subpart 3413. The third subpart 3411 is located on the side of the reflective part 321 away from the substrate 1. The fourth subpart 3412 is in contact with the second conductive part 311. The fifth subpart 3413 is connected between the third subpart 3411 and the fourth subpart 3412, and the fifth subpart 3413 has an angle β between the extension direction of the fifth subpart 3413 and the substrate 1, the angle β being acute.

It should be noted that FIG. 14 only shows the SEM image of the film layer structure in the middle part of the pixel region as shown in FIG. 3 or FIG. 4, and the SEM image for the edge region can be shown with reference to FIG. 17, in which the first conductive part 331 is not provided close to the pixel defining structure 38, i.e., there is a spacing between the first conductive part 331 and the pixel defining structure 38.

As shown in FIGS. 1 to 9, and 10, in some embodiments of the present disclosure, the display panel further includes a drive circuit layer 2 disposed between the substrate 1 and the light-emitting structure 3. The driver circuit layer 2 includes a driver circuit, and the driver circuit includes a pixel circuit, and the pixel circuit is used to drive the light-emitting device 30 of the display panel to emit light. The pixel circuit can be a pixel circuit such as 7T1C, 7T2C, 6T1C or 6T2C, and its structure is not particularly limited here. Here, nTmC indicates that a pixel circuit includes n transistors (indicated by the letter “T”) and m capacitors (indicated by the letter “C”). The pixel circuit is connected to the light-emitting device 30 one by one in correspondence to drive the light-emitting device 30 to emit light.

As shown in FIG. 10, in some embodiments of the present disclosure, the driver circuit layer 2 may include a multi-layer film structure. Taking the transistor in the driving circuit as an example of a top-gate type thin film transistor, the driver circuit layer 2 includes an active layer 21, a first gate insulating layer 22, a first gate metal layer 23, a second gate insulating layer 24, a second gate metal layer 25, an interlayer dielectric layer 26, and a source and drain layer 27.

The active layer 21 is provided on one side of the substrate 1; the first gate insulating layer 22 is provided on the side of the active layer 21 away from the substrate 1, and the first gate insulating layer 22 covers the active layer 21; the first gate metal layer 23 is provided on the side of the first gate insulating layer 22 away from the substrate 1, and the first gate metal layer 23 is used to form the first electrode plate of the capacitor C and the gate of the transistor T; the second gate insulating layer 24 is provided on the side of the first gate metal layer 23 away from the substrate 1, and the second gate insulating layer 24 covers the first gate metal layer 23; the second gate metal layer 25 is provided on the side of the first gate insulating layer 22 away from the substrate 1 and is directly opposite the first electrode plate, and the second gate metal layer 25 is used to form the second electrode plate of the capacitor C; the interlayer dielectric layer 26 is provided on the side of the second gate metal layer 25 away from the substrate 1, and the interlayer dielectric layer 26 covers the second gate metal layer 25; the source and drain layer 27 is provided on the side of the interlayer dielectric layer 26 away from the substrate 1, and the source and drain layer 27 is used to form the source 27S and the drain 27D of the transistor, and the source 27S and the drain 27D are connected to the active layer 21.

In some embodiments of the present disclosure, the driver circuit layer 2 further includes a buffer layer BFL, disposed between the active layer 21 and the substrate 1.

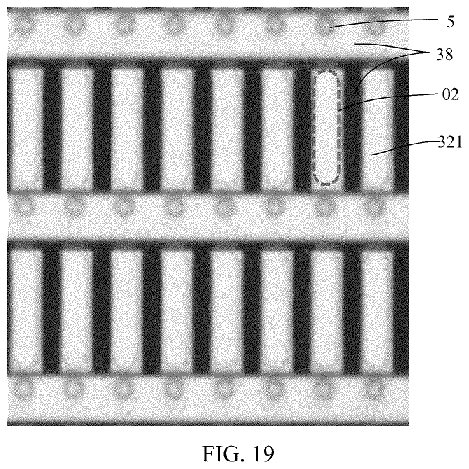

As shown in FIG. 1, FIG. 10, FIG. 18, and FIG. 19, in some embodiments, the display panel further includes a planarization layer PLN. The planarization layer PLN is provided on the side of the light-emitting structure 3 close to the substrate 1, and the anode 301 of the light-emitting device 30 may be connected to the pixel circuit through a via hole in the planarization layer PLN to drive the light-emitting device 30 to emit light.

When the second conductive part 311, the reflective part 321 and the first conductive part 331 serve as the anode 301 of the light-emitting device 30, the light-emitting device 30 may be connected to the source or drain of the transistor in the pixel circuit through a via hole by any one of the first conductive part 331, the reflective part 321 and the second conductive part 311. The actual connection may be shown with reference to FIG. 18, in which the light-emitting device is connected to the source or drain of the transistor in the pixel circuit through the via hole 5 by any one of the first conductive part 331, the reflective part 321, and the second conductive part 311.

When the first conductive part 331 is used as the anode 301 of the light-emitting device 30, the first conductive part 331 may be connected to the source or drain of the transistor in the pixel circuit through the via hole. When the first conductive part 331 and the reflective part 321 are used as the anode 301 of the light-emitting device 30, the first conductive part 331 or the reflective part 321 may be connected to the source or drain of the transistor in the pixel circuit through the via hole.

As shown in FIG. 1 and FIG. 19, in some embodiments of the present disclosure, the first conductive part 331 is connected to the pixel circuit through the via hole 5 in the planarization layer PLN, and the orthographic projection of the via hole 5 on the substrate 1 and the orthographic projection of the pixel defining structure 38 on the substrate 1 at least partially overlap. Of course, in other embodiments, when the anode 301 of the light-emitting device 30 is connected to the pixel circuit through the second conductive part 311 and the via hole in the planarization layer PLN, the orthographic projection of the via hole on the substrate 1 and the orthographic projection of the pixel defining structure 38 on the substrate 1 may also at least partially overlap. In these embodiments, the via hole in the planarization layer PLN is provided at the position of the pixel defining structure 38, which helps to enhance the opening ratio of the display panel, etc., to a certain extent.

It should be noted that when the SEM image shown in FIG. 19 is obtained, the microscope only turns on the top light and does not turn on the bottom light, and the reflective part 321 reflects light, so the brightness is relatively high. Some areas of the pixel defining structure 38 have a light-blocking structure and some areas do not have a light-blocking structure, so they show different brightness in different areas, with the areas with a light-blocking structure being dark and the areas without a light-blocking structure being bright.

As shown in FIG. 1, the present disclosure further provides a method for manufacturing a display panel, including the following steps S100 and S200.

Step S100, providing a substrate 1.

Step S200, forming a light-emitting structure 3 on one side of the substrate 1.

Here, step S200 includes the following steps S210 to S240.

Step S210, forming a reflective layer 32 on one side of the substrate 1, where the reflective layer 32 includes a plurality of reflective parts 321 spaced apart.

Step S220, forming a first conductive layer 33 on one side of the reflective layer 32 away from the substrate 1, where the first conductive layer 33 includes a plurality of first conductive parts 331 spaced apart.

Step S230, forming a defining structures 38 on one side of the substrate 1, where the pixel defining structure 38 defines a plurality of pixel regions in an array, and the plurality of reflective parts 321 are located within the plurality of pixel regions.

Step S240, forming a hole injection layer 361 on a side of the first conductive layer 33 away from the substrate 1, where the hole injection layer 361 includes a first subpart 3611 and a second subpart 3612, the first subpart 3611 is located in a middle portion of the pixel region, the second subpart 3612 is located in an edge portion of the pixel region, and a distance between the middle portion of the pixel region and the pixel defining structure 38 is greater than or equal to a distance between the edge portion of the pixel region and the pixel defining structure 38; and in a direction perpendicular to the substrate 1, at least a portion of the second subpart 3612 has a size greater than a size of the first subpart 3611.

Here, the plurality of reflective parts 321 have a one-to-one correspondence with the plurality of first conductive parts 331, and an orthographic projection of the first conductive part 331 on the substrate 1 at least partially overlaps with an orthographic projection of the reflective part 321 on the substrate 1.

In the direction parallel to the substrate 1, a spacing is provided between a side of the reflective part 321 close to the pixel defining structure 38 and a corresponding side of the pixel defining structure 38 close to the reflective part 321, or a spacing is provided between a side of the first conductive part 331 close to the pixel defining structure 38 and a corresponding side of the pixel defining structure 38 close to the first conductive part 331.

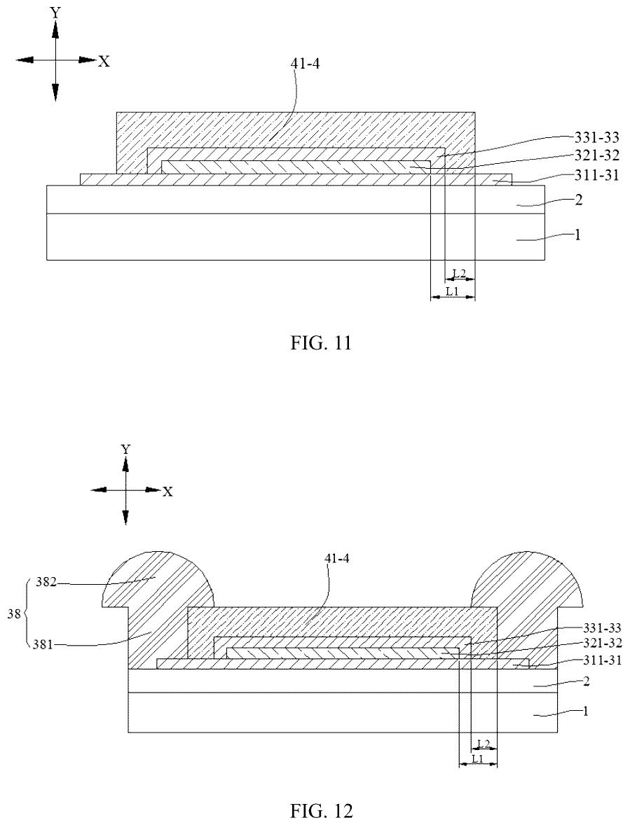

As shown in FIGS. 11 to 13, in some embodiments, step S240 includes the following steps S241 to S243.

Step S241, as shown in FIG. 11, forming a pre-embedded layer 4 on a side of the first conductive layer 33 away from the substrate 1, where the pre-embedded layer 4 includes a plurality of pre-embedded part 41 spaced apart, the pre-embedded part 41 covers the surface of the first conductive part 331 away from the substrate 1, and the pre-embedded part 41 cover at least the sidewalls of the first conductive part 331 and the reflective part 321. The material of the pre-embedded layer 4 may include a metal material. In the direction parallel to the substrate 1, the distance between the side of the pre-embedded part 41 away from the reflective part 321 and the side of the reflective part 321 close to the pre-embedded part 41 is equal to the first spacing L1; and in the direction parallel to the substrate 1, the distance between the side of the pre-embedded part 41 away from the first conductive part 331 and the side of the first conductive part 331 close to the pre-embedded part 41 is equal to the second spacing L2. The first spacing L1 may be the sum of the second spacing L2 and the thickness of the first conductive layer 33.

Step S242, forming a pixel defining structure 38 as shown in FIG. 12, where the pixel defining structure 38 covers at least a portion of the top surface of the pre-embedded part 41 and the sidewall of the pre-embedded part 41.

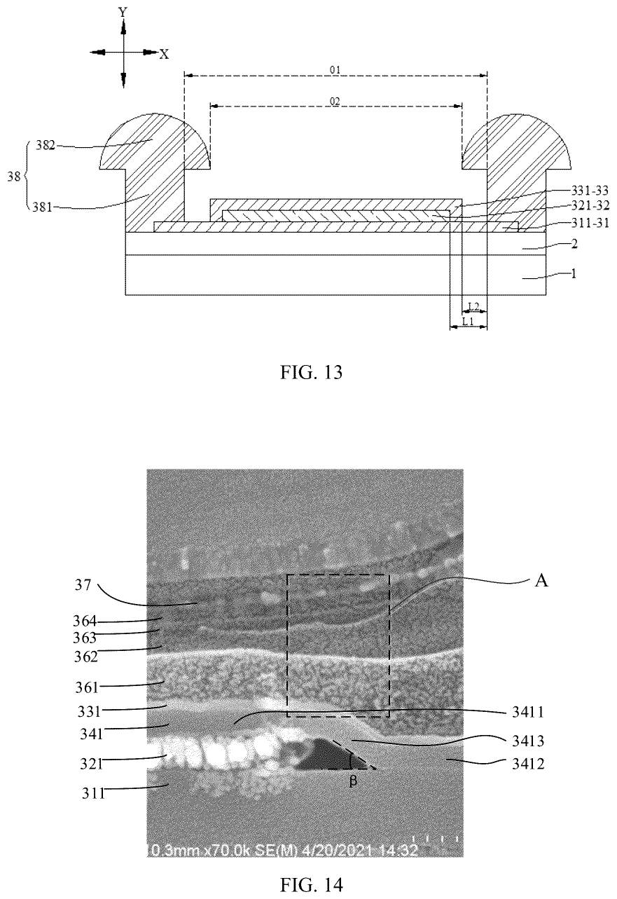

Step S243, removing the pre-embedded layer 4 as shown in FIG. 13.

The embodiments of the present disclosure also provide a display device, including a display panel, which may be a display panel of any of the above embodiments, the specific structure and beneficial effects of which may be referred to the above embodiments of the display panel, and will not be repeated here. The display device of the present disclosure can be a cell phone, tablet computer, television and other electronic devices, which will not be listed here.

It should be noted that although the steps of the method in the present disclosure are shown in the accompanying drawings in a particular order, it is not required or implied that the steps must be performed in that particular order or that all of the steps shown must be performed to achieve the desired result. Additional or alternatively, certain steps may be omitted, multiple steps may be combined into one step for execution, and/or one step may be decomposed into multiple steps for execution, etc., all of which should be considered as part of the present disclosure.

It should be understood that the present disclosure is not limited in its application to the detailed construction and arrangement of components set forth in this specification. The present disclosure can be provided with other embodiments and practiced and carried out in various ways. The foregoing variations and modifications fall within the scope of the present disclosure. It should be understood that the disclosure disclosed and defined in this specification expands to all alternative combinations of two or more of the individual features mentioned or evident in the text and/or drawings. All of these different combinations constitute alternative aspects of the present disclosure. The embodiments described herein illustrate the best mode known for carrying out the disclosure and will enable others skilled in the art to utilize the disclosure.

1. A display panel, comprising a substrate and a light-emitting structure on one side of the substrate, wherein the light-emitting structure comprises:
a pixel defining structure on one side of the substrate, configured to define a plurality of pixel regions arranged in an array, wherein a distance between a middle portion of a pixel region and the pixel defining structure, is equal to or greater than a distance between an edge portion of the pixel region and the pixel defining structure;
a reflective layer on one side of the substrate, comprising a plurality of reflective parts spaced apart, a reflective part being within the pixel region;
a first conductive layer on one side, away from the substrate, of the reflective layer, the first conductive layer comprising a plurality of first conductive parts spaced apart; and
a hole injection layer on one side, away from the substrate, of the first conductive layer, the hole injection layer comprising a first subpart and a second subpart, wherein the first subpart is disposed in the middle portion of the pixel region, and the second subpart is disposed in the edge portion of the pixel region; and in a direction perpendicular to the substrate, at least a portion of the second subpart has a size greater than a size of the first subpart;
wherein one reflective part corresponds to one first conductive part, and an orthographic projection of the first conductive part on the substrate at least partially overlaps with an orthographic projection of the reflective part on the substrate; and
in a direction parallel to the substrate, a first spacing is provided between a side of the reflective part close to the pixel defining structure and a corresponding side of the pixel defining structure close to the reflective part, and/or a second spacing is provided between a side of the first conductive part close to the pixel defining structure and a corresponding side of the pixel defining structure close to the first conductive part.

2. The display panel according to claim 1, wherein an orthographic projection of the first subpart on the substrate overlaps with the orthographic projection of the reflective part on the substrate, and an overlapping area, between an orthographic projection of the second subpart on the substrate and the orthographic projection of the reflective part on the substrate, is zero; and/or
an orthographic projection of the first subpart on the substrate overlaps with the orthographic projection of the first conductive part on the substrate, and an overlapping area, between an orthographic projection of the second subpart on the substrate and the orthographic projection of the first conductive part on the substrate, is zero.

3. (canceled)

4. The display panel according to claim 1, wherein the light-emitting structure further comprises:
a second conductive layer between the substrate and the reflective layer, comprising a plurality of second conductive parts spaced apart, wherein
an orthographic projection of the pixel region on the substrate is within an orthographic projection of a second conductive part on the substrate; and
in the direction perpendicular to the substrate, one reflective part corresponds to one second conductive part, and an orthographic projection of the second conductive part on the substrate at least partially overlaps with the orthographic projection of the reflective part on the substrate.

5. The display panel according to claim 4, wherein the pixel defining structure has, in the direction perpendicular to the substrate, a bottom end close to the substrate, a top end away from the substrate, and a middle part between the bottom end and the top end, the bottom end of the pixel defining structure is configured to defines a plurality of openings, the middle part or the top end of the pixel defining structure is configured to define a plurality of light outlets, and one opening corresponds to one second conductive part to expose the second conductive part;
an orthographic projection of a light outlet on the substrate is within an orthographic projection of the opening on the substrate; and
the orthographic projection of the light outlet on the substrate, the orthographic projection of the reflective part on the substrate, and the orthographic projection of the first conductive part on the substrate are at least partially overlapped.

6. The display panel according to claim 31, wherein along a direction away from the substrate, the pixel defining structure comprises a first part and a second part connected in sequence; and
an orthographic projection of the first part on the substrate is within an orthographic projection of the second part on the substrate, and an area of the orthographic projection of the first part on the substrate is smaller than an area of the orthographic projection of the second part on the substrate.

7. The display panel according to claim 6, wherein an overlapping area between the orthographic projection of the first conductive part on the substrate and the orthographic projection of the reflective part on the substrate, do not overlap with the orthographic projection of the second part on the substrate; and
at least a portion of an orthographic projection of the first spacing or the second spacing on the substrate is within the orthographic projection of the second part on the substrate.

8. The display panel according to claim 6, wherein in the direction perpendicular to the substrate, a height of the first part is greater than or equal to a sum of a thickness of the reflective part and a thickness of the first conductive part.

9. The display panel according to claim 6, wherein in the direction perpendicular to the substrate, a side, away from the substrate, of a cross section of the second part is an arc protruding in a direction away from the substrate; and/or
a cross section of the pixel defining structure is in a mushroom shape.

10. (canceled)

11. The display panel according to claim 1, wherein the reflective part has a first surface close to the substrate, a second surface away from the substrate, and a sidewall between the first surface and the second surface, the first conductive part contacting the sidewall and the second surface of the reflective part.

12. The display panel according to claim 4, wherein the light-emitting structure further comprises:
a first insulating layer between the reflective layer and the first conductive layer, the first insulating layer comprising a plurality of first insulating parts spaced apart, wherein a first insulating part is within the pixel region, and the orthographic projection of the reflective part on the substrate is within an orthographic projection of the first insulating part on the substrate.

13. The display panel according to claim 12, wherein the first insulating part contacts a sidewall of the reflective part and a surface of the reflective part on a side away from the substrate, and the first insulating part contacts an area of the second conductive part exposed by the reflective part.

14. The display panel according to claim 4, wherein the light-emitting structure further comprises:
a second insulating layer on a side of the second conductive layer away from the substrate, the second insulating layer comprising a plurality of second insulating parts spaced apart, wherein
a second insulating part is within the pixel region, and the second insulating part contacts an area of the second conductive part exposed by the reflective part, a sidewall of the first conductive part, a sidewall of the reflective part, and at least a portion of a surface of the first conductive part away from the substrate.

15. (canceled)

16. The display panel according to claim 4, further comprising:
a planarization layer on a side of the light-emitting structure close to the substrate, wherein
the first conductive part is connected to a pixel circuit through a via hole in the planarization layer, and an orthographic projection of the via hole on the substrate and an orthographic projection of the pixel defining structure on the substrate are at least partially overlapped.

17. The display panel according to claim 12, wherein the first insulating part comprises:
a third subpart on a side of the reflective part away from the substrate;
a fourth subpart in contact with the second conductive part; and
a fifth subpart connected between the third subpart and the fourth subpart, wherein an angle is between an extension direction of the fifth subpart and the substrate, the angle being acute.

18. The display panel according to claim 1, further comprising:
a planarization layer on a side of the light-emitting structure close to the substrate, wherein
the orthographic projection of the first conductive part on the substrate and an orthographic projection of the pixel defining structure on the substrate are at least partially overlapped; and
the first conductive part is in contact, at least in part, with the planarization layer.

19. The display panel according to claim 4, further comprising:
a first insulating layer between the reflective layer and the first conductive layer, the first insulating layer comprising a plurality of first insulating parts spaced apart, wherein a first insulating part at least partially covers a portion of the second conductive part exposed by the reflective part.

20. A method for manufacturing a display panel, comprising:
providing a substrate; and
forming a light-emitting structure on one side of the substrate;
wherein forming the light-emitting structure on the side of the substrate comprises:
forming a reflective layer on one side of the substrate, wherein the reflective layer comprises a plurality of reflective parts spaced apart;
forming a first conductive layer on one side of the reflective layer away from the substrate, wherein the first conductive layer comprises a plurality of first conductive parts spaced apart;
forming a pixel defining structure on one side of the substrate, wherein the pixel defining structure configured to defines a plurality of pixel regions arranged in an array, one reflective part being within a pixel region; and a distance between a middle portion of a pixel region and the pixel defining structure, is equal to or greater than a distance between an edge portion of the pixel region and the pixel defining structure; and
forming a hole injection layer on one side of the first conductive layer away from the substrate, wherein the hole injection layer comprises a first subpart and a second subpart, the first subpart is disposed in the middle portion of the pixel region, and the second subpart is disposed in the edge portion of the pixel region; and in a direction perpendicular to the substrate, at least a portion of the second subpart has a size greater than a size of the first subpart;
wherein one reflective part corresponds to one first conductive part, and an orthographic projection of the first conductive part on the substrate at least partially overlaps with an orthographic projection of the reflective part on the substrate; and
in a direction parallel to the substrate, a first spacing is provided between a side of the reflective part close to the pixel defining structure and a corresponding side of the pixel defining structure close to the reflective part, and/or a second spacing is provided between a side of the first conductive part close to the pixel defining structure and a corresponding side of the pixel defining structure close to the first conductive part.

21. The method for manufacturing the display panel according to claim 20, wherein forming the pixel defining structure on one side of the substrate comprises:
forming a pre-embedded layer on one side of the first conductive layer away from the substrate, the pre-embedded layer comprising a plurality of pre-embedded parts spaced apart, wherein a pre-embedded part covers a surface of the first conductive part away from the substrate, and the pre-embedded part covers at least a sidewall of the first conductive part and a sidewall of the reflective part;
forming the pixel defining structure, wherein the pixel defining structure covers at least a portion of a top surface of the pre-embedded part and a sidewall of the pre-embedded part; and
removing the pre-embedded layer.

22. The method for manufacturing the display panel according to claim 21, wherein in the direction parallel to the substrate, a distance, between a side of the pre-embedded part away from the reflective part and a side of the reflective part close to the pre-embedded part, is equal to the first spacing.

23. A display device comprising a display panel according to claim 1.
